(19) United States
(12) Patent Application Publication
(10) Pub. No.: US 2017/0153305 A1
(43) Pub. Date: Jun. 1, 2017

(54) SWITCHING APPARATUS, MAGNETIC RESONANCE IMAGING APPARATUS INCLUDING THE SAME, AND METHOD FOR CONTROLLING THE MAGNETIC RESONANCE IMAGING APPARATUS

(71) Applicant: SAMSUNG ELECTRONICS CO., LTD., Suwon-si (KR)

(72) Inventors: Hyun-Woo KIM, Suwon-si (KR); Han Lim LEE, Seoul (KR); Ju Hyung LEE, Gwacheon-si (KR)

(73) Assignee: SAMSUNG ELECTRONICS CO., LTD., Suwon-si (KR)

(21) Appl. No.: 15/366,653

(22) Filed: Dec. 1, 2016

(30) Foreign Application Priority Data
Dec. 1, 2015 (KR) 10-2015-0169921

(51) Int. Cl. G01R 33/36; G01R 33/54; G01R 33/34

(52) U.S. Cl. CPC G01R 33/3657; G01R 33/34092; G01R 33/543

(57) ABSTRACT

A device for switching a connection relationship between an input channel and an output channel group determined according to a selection mode, a magnetic resonance imaging (MRI) apparatus including the switching device, and a method for controlling the MRI apparatus are disclosed. The device includes: a plurality of input channels capable of being respectively connected to a plurality of coils, each of which receives a radio frequency (RF) signal from a target object to which a magnetic field is applied; a plurality of output channels capable of being connected to an image processor designed to generate a magnetic resonance image on the basis of the received RF signal; and a switching portion configured to switch a connection relationship between the plurality of input channels and the plurality of output channels. If a first mode or a second mode is selected, the switching portion performs switching so that a first output channel group including the plurality of output channels outputs, or so that a second output channel group including predetermined parts from among the plurality of output channels outputs, the RF signal.

### CROSS-REFERENCE TO RELATED APPLICATION

This application claims the benefit of Korean Patent Application No. 10-2015-0169921, filed on Dec. 1, 2015 in the Korean Intellectual Property Office, the disclosure of which is incorporated herein by reference.

### BACKGROUND

1. Field

Exemplary embodiments of the present disclosure relate to a switching apparatus for switching a connection relationship between an input channel and an output channel of Radio Frequency (RF) signals, a magnetic resonance imaging (MRI) apparatus including the same, and a method for controlling the magnetic resonance imaging apparatus.

2. Description of the Related Art

In general, an image processing apparatus (e.g., a medical imaging device) is a device which acquires information of a patient and provides an image of the acquired information. For example, the image processing apparatus includes an X-ray imaging device, an ultrasonic diagnostic device, a computed tomography (CT) scanner, a magnetic resonance imaging (MRI) apparatus, and the like.

The magnetic resonance imaging (MRI) apparatus among these devices provides a relatively free imaging condition, high contrast in soft tissue, and a variety of diagnostic information images. Accordingly, the magnetic resonance imaging (MRI) apparatus occupies a prominent place in the medical image diagnostic field.

The MRI apparatus causes nuclear magnetic resonance in the hydrogen atomic nuclei of the human body using a magnetic field that is harmless to humans and RF which is non-ionizing radiation, to thereby image the densities and physical or chemical characteristics of the atomic nuclei.

Specifically, the magnetic resonance imaging (MRI) apparatus is an image diagnosis device that supplies a uniform frequency and energy to atomic nuclei in a state in which a uniform magnetic field is applied to the atomic nuclei and converts energy emitted from the atomic nuclei into a signal to diagnose the interior of the human body.

In this case, an RF coil may be used to receive energy emitted from atomic nuclei, and the RF coil may be separated from a patient table as necessary. Generally, the RF coil may be separated from the patient table when not in use, and may be connected to the patient table during MRI processing.

### SUMMARY

Therefore, it is an aspect of the present disclosure to provide a switching apparatus for switching a connection relationship between an input channel and an output channel group determined according to a selection mode, a magnetic resonance imaging (MRI) apparatus including the switching device, and a method for controlling the MRI apparatus.

Additional aspects of the invention will be set forth in part in the description which follows and, in part, will be obvious from the description, or may be learned by practice of the invention.

In accordance with one aspect of the present disclosure, a switching device includes: a plurality of input channels capable of being respectively connected to a plurality of coils, each of which receives a radio frequency (RF) signal from a target object to which a magnetic field is applied; a plurality of output channels capable of being connected to an image processor designed to generate a magnetic resonance image on the basis of the received RF signal; and a switching portion configured to switch a connection relationship between the plurality of input channels and the plurality of output channels. If a first mode is selected, the switching portion performs switching of the connection relationship in a manner so that a first output channel group including the plurality of output channels outputs the RF signal. If a second mode is selected, the switching portion performs switching of the connection relationship in a manner so that a second output channel group including predetermined parts from among the plurality of output channels outputs the RF signal.

The number of output channels contained in the first output channel group may be two times the number of output channels contained in the second output channel group. The number of input channels may be two times the number of output channels contained in the first output channel group.

The switching portion may include a plurality of switching cells, each of which is configured to perform switching of a connection relationship between 8 input channels and 4 output channels.

If the first mode is selected, the switching cell may perform switching of the connection relationship in a manner so that the first output channel group including all the four output channels outputs the RF signal. If the second mode is selected, the switching cell may perform switching of the connection relationship in a manner so that the second output channel group including two output channels from among the four output channels outputs the RF signal.

The switching cell may include: a primary switching portion configured to perform switching of a connection relationship between primary input channels connected to the 8 input channels and 4 primary output channels; and a secondary switching portion configured to perform switching of a connection relationship between the 4 primary output channels and the first output channel group when the first mode is selected, and configured to perform switching of a connection relationship between the 4 primary output channels and the second output channel group when the second mode is selected.

The primary switching portion may include: a first lower switching portion configured to perform switching of a connection relationship between four of the primary input channels and two of the primary output channels; and a second lower switching portion configured to perform switching of a connection relationship between the remaining four of the primary input channels and the remaining two of the primary output channels.

The secondary switching portion may include: a third lower switching portion configured to perform switching of a connection relationship between secondary input channels connected to the four primary output channels and two secondary output channels connected to the second output channel group when the second mode is selected.

The secondary switching portion may further include a mode selection portion configured to connect the four primary output channels to the first output channel group when the first mode is selected.

In accordance with another aspect of the present disclosure, a magnetic resonance imaging apparatus includes: a radio frequency (RF) coil in which a plurality of coils, each of which receives an RF signal from a target object to which a magnetic field is applied, is arranged; an image processor configured to generate a magnetic resonance image on the basis of the received RF signal; and a switching device configured to perform switching of a connection relationship between a plurality of input channels capable of being connected to the plurality of coils and a plurality of output channels capable of being connected to the image processor. If a first mode is selected, the switching device may perform switching of the connection relationship in a manner so that a first output channel group including the plurality of output channels outputs the RF signal. If a second mode is selected, the switching device may perform switching of the connection relationship in a manner so that a second output channel group including predetermined parts from among the plurality of output channels outputs the RF signal.

The number of output channels contained in the first output channel group may be two times the number of output channels contained in the second output channel group. The number of input channels may be two times the number of output channels contained in the first output channel group.

The switching device may include a plurality of switching cells, each of which is configured to perform switching of a connection relationship between 8 input channels and 4 output channels.

If the first mode is selected, the switching cell may perform switching of the connection relationship in a manner so that the first output channel group including all the four output channels outputs the RF signal. If the second mode is selected, the switching cell may perform switching of the connection relationship in a manner so that the second output channel group including two output channels from among the four output channels outputs the RF signal.

The switching cell may includes: a primary switching portion configured to perform switching of a connection relationship between primary input channels connected to the 8 input channels and 4 primary output channels; and a secondary switching portion configured to perform switching of a connection relationship between the 4 primary output channels and the first output channel group when the first mode is selected, and configured to perform switching of a connection relationship between the 4 primary output channels and the second output channel group when the second mode is selected.

The primary switching portion may include: a first lower switching portion configured to perform switching of a connection relationship between four of the primary input channels and two of the primary output channels; and a second lower switching portion configured to perform switching of a connection relationship between the remaining four of the primary input channels and the remaining two of the primary output channels.

The secondary switching portion may include: a third lower switching portion configured to perform switching of a connection relationship between secondary input channels connected to the four primary output channels and two secondary output channels connected to the second output channel group when the second mode is selected.

The secondary switching portion may further include: a mode selection portion configured to connect the four primary output channels to the first output channel group when the first mode is selected.

In accordance with another aspect of the present disclosure, a method for controlling a magnetic resonance imaging apparatus which includes a switching device configured to perform switching of a connection relationship between a plurality of input channels capable of being connected to a plurality of coils each receiving a radio frequency (RF) signal from a target object and a plurality of output channels capable of being connected to an image processor includes: confirming a selected mode of the switching device; and switching the connection relationship according to the selected mode. The switching the connection relationship may include: if a first mode is selected by the switching device, switching the connection relationship in a manner so that a first output channel group including the plurality of output channels outputs the RF signal, and if a second mode is selected by the switching device, switching the connection relationship in a manner so that a second output channel group including predetermined parts from among the plurality of output channels outputs the RF signal.

The number of output channels contained in the first output channel group may be two times the number of output channels contained in the second output channel group. The number of input channels may be two times the number of output channels contained in the first output channel group.

The switching device includes: a plurality of switching cells, each of which is configured to perform switching of a connection relationship between 8 input channels and 4 output channels. The switching the connection relationship according to the selected mode may include switching a connection relationship between the respective switching cells according to the selected mode.

The switching the connection relationship when a first mode is selected by the switching device may include switching the connection relationship in a manner so that the first output channel group including all the four output channels of the switching cell outputs the RF signal. The switching the connection relationship when a second node is selected by the switching device may include switching the connection relationship in a manner so that the second output channel group including two output channels from among the four output channels of the switching cell outputs the RF signal.

The switching the connection relationship according to the selected mode may further include: switching a connection relationship between primary input channels of a primary switching portion of the switching cell connected to the 8 input channels and 4 primary output channels of the primary switching portion of the switching cell.

The switching the connection relationship when the first mode is selected by the switching device may include switching a connection relationship between the 4 primary output channels and the first output channel group. The switching the connection relationship when the second mode is selected by the switching device may include switching a connection relationship between the four primary output channels and the second output channel group.

The switching the connection relationship when the second mode is selected by the switching device may include: switching a connection relationship between a secondary input channel of a secondary switching portion of the switching cell connected to the four primary output channels and two secondary output channels of the secondary switching portion of the switching cell connected to the second output channel group.

The switching the connection relationship when the first mode is selected by the switching device may include connecting the four primary output channels to the first output channel group.

In an exemplary embodiment, there is a switching device including: a plurality of input channels configured to be respectively connected to a plurality of coils, the plurality of input channels receiving a plurality of radio frequency (RF) signals from a target object to which a magnetic field is applied; a plurality of output channels configured to be connected to an image processor, the image processor being configured to generate a magnetic resonance image based on the received plurality of RF signals; and a switching portion configured to switch a connection relationship between the plurality of input channels and the plurality of output channels. If a first mode is selected, the switching portion is further configured to switch the connection relationship in a manner so that a first output channel group including the plurality of output channels outputs the plurality of RF signals, and if a second mode is selected, the switching portion is further configured to switch the connection relationship in a manner so that a second output channel group including predetermined parts from among the plurality of output channels, outputs the plurality of RF signals.

In yet another exemplary embodiment, there is a magnetic resonance imaging apparatus including: a radio frequency (RF) coil in which a plurality of coils receives a plurality of RF signals from a target object to which a magnetic field is applied, is arranged; an image processor configured to generate a magnetic resonance image based on the received plurality of RF signals; and a switching device configured to perform switching of a connection relationship between a plurality of input channels operable to be connected to the plurality of coils and a plurality of output channels operable to be connected to the image processor. If a first mode is selected, the switching device performs switching of the connection relationship in a manner so that a first output channel group including the plurality of output channels outputs the plurality of RF signals, and if a second mode is selected, the switching device performs switching of the connection relationship in a manner so that a second output channel group including predetermined parts from among the plurality of output channels outputs the plurality of RF signals.

In one exemplary embodiment, there is a method for controlling a magnetic resonance imaging apparatus which includes a switching device configured to perform switching of a connection relationship between a plurality of input channels operable to be connected to a plurality of coils receiving a plurality of radio frequency (RF) signals from a target object and a plurality of output channels operable to be connected to an image processor, the method including: confirming a selected mode of the switching device; and switching the connection relationship according to the selected mode. The switching the connection relationship includes: if a first mode is selected by the switching device, switching the connection relationship in a manner so that a first output channel group including the plurality of output channels outputs the plurality of RF signals, and if a second mode is selected by the switching device, switching the connection relationship in a manner so that a second output channel group including predetermined parts from among the plurality of output channels outputs the plurality of RF signals.

### BRIEF DESCRIPTION OF THE DRAWINGS

These and/or other aspects of the invention will become apparent and more readily appreciated from the following description of the exemplary embodiments, taken in conjunction with the accompanying drawings of which:

FIG. 1 is a block diagram illustrating a magnetic resonance imaging (MRI) apparatus according to an exemplary embodiment.

FIG. 2 is a view schematically illustrating an external appearance of the magnetic resonance imaging (MRI) apparatus according to an exemplary embodiment.

FIG. 3 is a view illustrating a space in which an object is placed, in the X-axis, Y-axis, and Z-axis.

FIG. 4 is a view illustrating a configuration of a magnet assembly and a configuration of a gradient coil portion according to an exemplary embodiment.

FIG. 5 shows pulse sequences associated with the operation of respective gradient coils contained in the gradient coil portion.

FIGS. 6A and 6B are conceptual diagrams illustrating various methods for allowing the switching apparatus to output signals according to an exemplary embodiment of the present disclosure.

FIG. 7 is a control block diagram illustrating a switching cell according to an exemplary embodiment of the present disclosure.

FIG. 8 is a circuit diagram illustrating a primary switching portion according to an exemplary embodiment of the present disclosure.

FIG. 9 is a circuit diagram illustrating a secondary switching portion according to an exemplary embodiment of the present disclosure.

FIG. 10 is a circuit diagram illustrating the operations generated when a first mode of the secondary switching portion is selected.

FIGS. 11A and 11B are circuit diagrams illustrating the operations generated when a second mode of the secondary switching portion is selected.

FIG. 12 is a flowchart illustrating a method for controlling the switching apparatus according to an exemplary embodiment of the present disclosure.

### DETAILED DESCRIPTION

Reference will now be made in detail to the exemplary embodiments of the present disclosure, examples of which are illustrated in the accompanying drawings, wherein like reference numerals refer to like elements throughout.

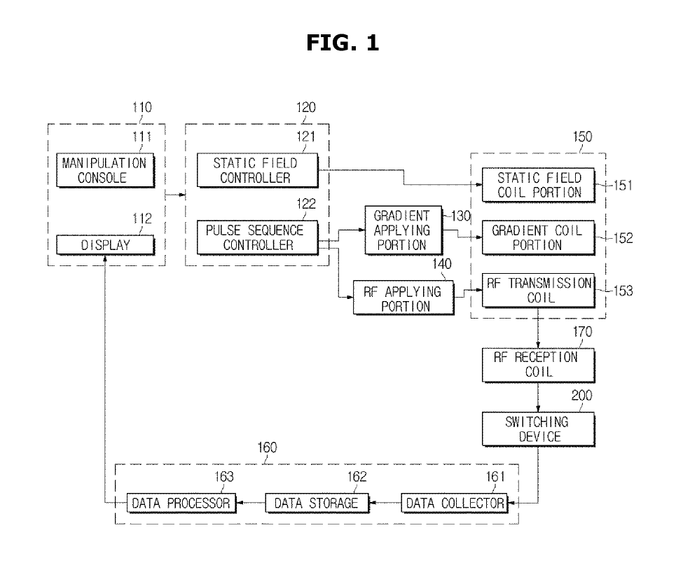

FIG. 1 is a block diagram illustrating a magnetic resonance imaging (MRI) apparatus according to an exemplary embodiment. The MRI apparatus will hereinafter be described with reference to FIG. 1. Specifically, it is assumed that a radio frequency (RF) reception coil is separated from a magnet assembly for convenience of description and better understanding of the present disclosure. In another exemplary embodiment, the RF reception coil is included in a magnet assembly.

Referring to FIG. 1, the MRI apparatus may include a magnet assembly 150 to create a magnetic field as well as to cause resonance of atomic nuclei; a controller 120 to control the magnet assembly 150; and an image processor 160 to generate MRI images on the basis of an echo signal (i.e., a magnetic resonance signal) generated from the atomic nuclei. The MRI apparatus may further include an RF reception coil 170 to receive a magnetic resonance signal generated from the magnet assembly and to transmit the received magnetic resonance signal to the image processor, and a switching device 200 to establish a communication path from the magnetic resonance signal received by the RF reception coil to the image processor.

The magnet assembly 150 may include a static field coil portion 151 to form a static field in an inner space thereof, a gradient coil portion 152 to form a gradient field by generating a gradient in the static field, and an RF transmission coil 153 to generate RF pulses. That is, if a target object is placed in the inner space of the magnet assembly 150, the static field, the gradient field, and the RF pulses may be applied to the target object. Atomic nuclei constructing the target object may be excited by RF pulses, such that echo signals may be generated.

The RF reception coil 170 may receive RF signals (i.e., magnetic resonance signals) emitted from the excited atomic nuclei. The RF reception coil 170 is often designed to be attached to the human body, such that the RF reception coil 170 is generally implemented as a head coil, a neck coil, a waist coil, and the like to follow the contour of each human body region.

One example of the RF reception coil 170 separable from the magnet assembly 150 is a surface coil configured to receive a magnetic resonance signal from an excited region of the target object. The surface coil has a significantly high signal to noise ratio (SNR) relative to a proximate region because it is smaller than a volume coil and takes the form of a 2-dimensional (2D) plane.

Another example of the RF reception coil 170 is an array coil in which several surface coils are arranged in a 1D or 2D space to increase the size of a reception area. The array coil has variable arrangement depending on an imaging region, and is classified into a head coil, a head and neck coil, a chest coil, a spine coil, an abdomen coil, a leg coil, and the like. The respective surface coils of the array coil have different relative positions, and thus have a difference between phases of signals received by the respective surface coils. Accordingly, when reconstructing an image by synthesizing signals received by the respective surface coils, an image having a high signal to noise ratio (SNR) may be acquired in consideration of a reception phase of the surface coils.

The controller 120 includes a static field controller 121 to control the strength and direction of a static magnetic field created by the static magnetic field coil portion 151, and a pulse sequence controller 122 to control the gradient coil portion 152 and the RF transmission coil 153 based on a pulse sequence.

The magnetic resonance imaging (MRI) apparatus 100 further includes a gradient applying portion 130 to apply a gradient signal to the gradient coil portion 152, and an RF applying portion 140 to apply an RF signal to the RF transmission coil 153. The pulse sequence controller 122 may control the gradient applying portion 130 and the RF applying portion 140, such that it can adjust not only the gradient field formed in the inner space of the magnet assembly 150 but also RF signals applied to the atomic nuclei.

The image processor 160 may include a data collector 161 to receive data related to a spin echo signal (i.e. a magnetic resonance signal generated from atomic nuclei) and process the data so as to form a magnetic resonance image; a data storage 162 to store the data received by the data collector 161; and a data processor 163 to form a magnetic resonance image by processing the stored data.

The data collector 161 may include a preamplifier to amplify a magnetic resonance signal received by the RF reception coil 173; a phase detector to detect a phase upon receiving the magnetic resonance signal from the preamplifier; and an A/D converter to convert an analog signal acquired via phase detection into a digital signal. In addition, the data collector 161 transmits the digital magnetic resonance signal to the data storage 162.

The data storage 162 has a data space constituting a 2D Fourier space. When all scanned data is completely stored, the data processor 163 implements 2D inverse Fourier transformation of data in the 2D Fourier space to reconstruct an image of the object (ob). The reconstructed image may be displayed on a display 112.

In addition, the MRI apparatus 100 may include a user manipulator 110, which may receive a control command related to overall operation of the MRI apparatus 100 from a user. In particular, the user manipulator 110 may produce a pulse sequence upon receiving a command related to a scan sequence from the user.

The user manipulator 110 may include a manipulation console 111 to allow the user to operate a system; and the display 112 to display a control state and an image produced by the image processor 160 so as to allow the user to diagnose a health state of the object.

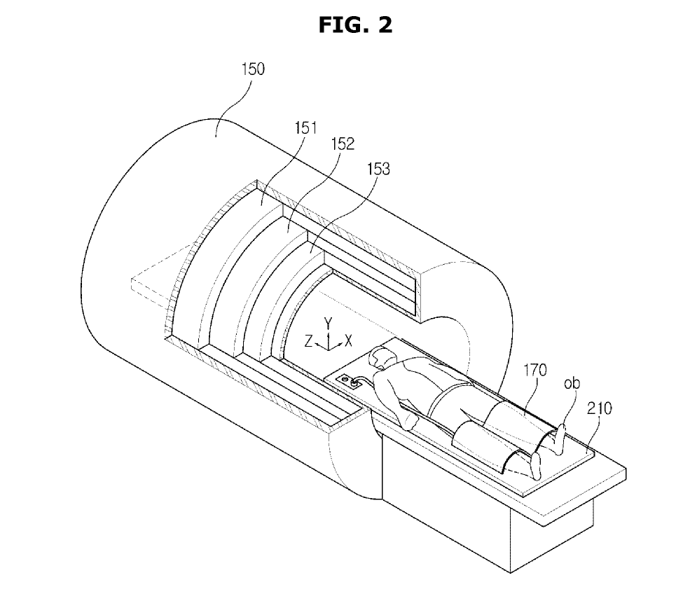

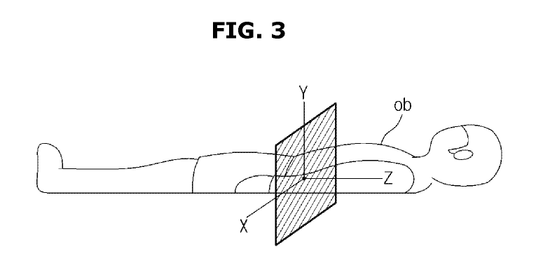

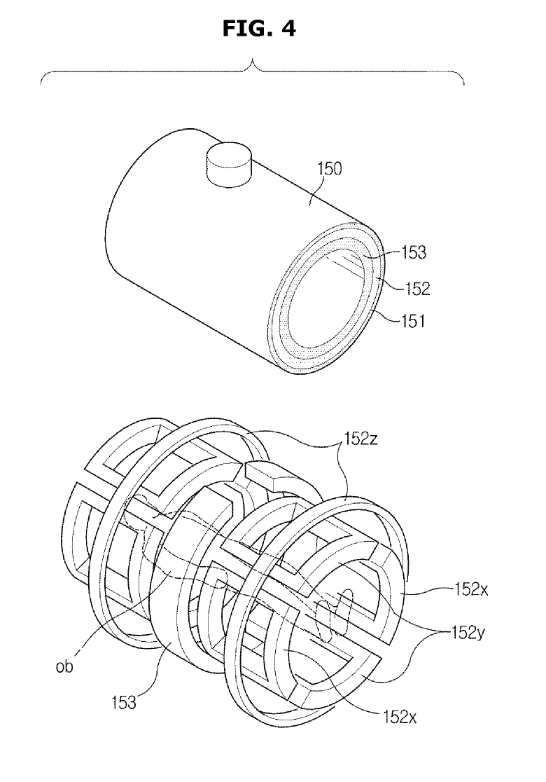

FIG. 2 is a view schematically illustrating an external appearance of the magnetic resonance imaging (MRI) apparatus according to an exemplary embodiment. FIG. 3 is a view illustrating a space in which an object is placed, in the X-axis, Y-axis, and Z-axis. FIG. 4 is a view illustrating a configuration of a magnet assembly and a configuration of a gradient coil portion according to an exemplary embodiment.

Hereinafter, operation of the MRI apparatus 100 according to one embodiment of the present disclosure will be described in detail with reference to FIG. 1.

Referring to FIG. 2, the magnet assembly 150 takes the form of a hollow cylinder having an empty inner space, and is referred to as a gantry or bore. The inner space of the magnet assembly 150 is referred to as a cavity. A patient table 210 serves to transport the object (ob) lying thereon into the cavity for acquisition of a magnetic resonance signal.

The magnet assembly 150 includes a static field coil portion 151, a gradient coil portion 152, and an RF transmission coil 153.

The static field coil portion 151 may have a structure in which coils are wound around the cavity. If current is applied to the static field coil portion 151, a static field is formed inside the magnet assembly 150, that is, in the cavity or bore.

The direction of the static field is generally parallel to a longitudinal axis of the magnet assembly 150, parallel to the Z-axis.

If the static field is formed in the cavity, the atomic nuclei of atoms (e.g., hydrogen atoms) configuring the target object (ob) are arranged in the direction of the static field, and perform precession with respect to the direction of the static field. The rate of precession of each atomic nucleus may be indicated as a precession frequency, the precession frequency, referred to as the Larmor frequency, is expressed by the following “Equation 1”.

ω=γB₀ [Equation 1]

Where, ω refers to a Larmor frequency, γ refers to a proportional constant, and B₀ refers to an intensity of an external magnetic field. The proportional constant differs for each type of atomic nucleus, the unit of the intensity of the external magnetic field is Tesla (T) or Gauss (G), and the unit of the precession frequency is Hz.

For example, since the hydrogen proton has a precession frequency of 42.58 MHz in an external magnetic field of 1T and hydrogen occupies the greatest proportion of atoms constituting the human body, the magnetic resonance signal is mainly obtained using the precession of the hydrogen proton in MRI.

The gradient coil portion 152 generates a gradient in the static field formed in the cavity to form a gradient magnetic field.

As shown in FIG. 3, an axis parallel to a vertical direction from the head to the feet of the object (ob), i.e., an axis parallel to the direction of a static field may be determined as the Z-axis, an axis parallel to a horizontal direction of the object (ob) may be determined as the X-axis, and an axis parallel to a vertical direction in the inner space may be determined as the Y-axis.

In order to obtain three-dimensional (3D) spatial information regarding the magnetic resonance signal, gradient magnetic fields are required for all of the x-, y-, and z-axes. Thus, the gradient coil portion 152 includes three pairs of gradient coils, i.e., the X-axis gradient coil 152x, the Y-axis gradient coil 152y, and the Z-axis gradient coil 152z.

As shown in FIG. 4, the Z-axis gradient coil 152z is generally composed of a pair of ring coils, and the Y-axis gradient coil 152y is located over and beneath the object (ob). The X-axis gradient coil 152x is located to the left and right of the object (ob).

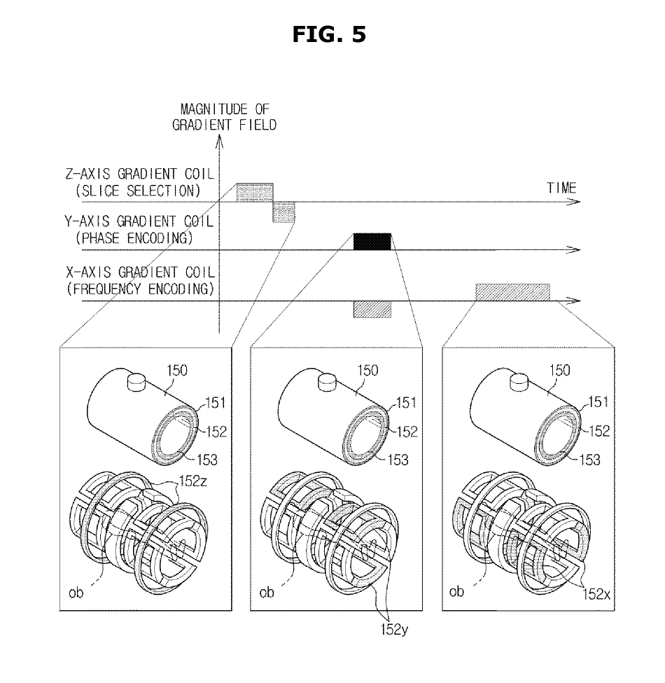

FIG. 5 shows pulse sequences associated with the operation of respective gradient coils contained in the gradient coil portion.

If direct currents having opposite polarities flow at the two respective Z-axis gradient coils 152z in opposite directions, a variation in magnetic field is generated in the Z-axis direction, resulting in a gradient magnetic field (also called a gradient field).

As the gradient field is created by current applied to the Z-axis gradient coil 152z for a given time, a resonance frequency increases or decrease based on the magnitude of the gradient magnetic field. Then, when a high-frequency signal corresponding to a specific position is applied via the RF transmission coil 153, only protons in a cross section corresponding to the specific position resonate. Thus, the Z-axis gradient coil 152z may be used to select a slice. As the gradient magnetic field created in the Z-axis direction increases, slice thickness decreases.

When a slice is selected through the gradient magnetic field formed by the Z-axis gradient coil 152z, all of spins constituting the slice have the same frequency and phase. Consequently, the spins may not be individually distinguished.

In this case, when a gradient magnetic field is formed in the Y-axis direction by the Y-axis gradient coil 152y, the gradient magnetic field generates a phase shift such that spins constituting rows of the slice have different phases from each other.

That is, when the Y-axis gradient magnetic field is formed, the spins in the rows to which a large gradient magnetic field is applied are phase-shifted to a high frequency and the spins in the rows to which a small gradient magnetic field is applied are phase-shifted to a low frequency. When the Y-axis gradient magnetic field disappears, the phase-shift is generated in each of the rows of the selected slice and the rows have different phases from each other. Consequently, the rows may be distinguished from each other. The gradient magnetic field generated by the Y-axis gradient coil 152y is used in phase encoding.

A slice is selected through the gradient magnetic field formed by the Z-axis gradient coil 152z, and rows constituting the selected slice are distinguished by different phases from each other through the gradient magnetic field formed by the Y-axis gradient coil 152y. However, since respective spins constituting the rows have the same frequency and phase, the spins may not be individually distinguished.

In this case, when a gradient magnetic field is formed in the X-axis direction by the X-axis gradient coil 152x, the gradient magnetic field allows the spins constituting the respective rows to have different frequencies from each other, thereby enabling the spins to be individually distinguished from each other. As such, the gradient magnetic field generated by the X-axis gradient coil 152x is used in frequency encoding.

As described above, the gradient magnetic fields formed by the z-, y-, and x-axes gradient coils spatially encode spatial positions of the respective spins via the slice selection, the phase encoding, and the frequency encoding, respectively.

The gradient coil portion 152 is connected to the gradient applying portion 130, and the gradient applying portion 130 42 applies a current pulse to the gradient coil portion 152 depending upon a control signal received from the pulse sequence controller 122 so as to generate the gradient magnetic field.

The gradient applying unit 42 may include three drive circuits corresponding to the three gradient coils 47, 48, and 49 constituting the gradient coil unit 21. Accordingly, the gradient applying portion 130 may be referred to as a gradient power source, and may have three drive circuits corresponding to the three gradient coils (152z, 152y, 152x) constituting the gradient coil portion 152.

As described above, the atomic nuclei aligned by the external magnetic field may precess according to the Larmor frequency, and a vector sum of magnetizations of several atomic nuclei may be indicated as one net magnetization M.

Since a z-axis component of the net magnetization is impossible to be measured, M_{xy} alone may be measured. Accordingly, the net magnetization has to be present on the X-Y plane by excitation of the atomic nuclei, in order to obtain a magnetic resonance signal. An RF pulse tuned to the Larmor frequency of the atomic nuclei has to be applied to a static magnetic field for excitation of the atomic nuclei.

The RF transmission coil 153 is connected to the RF applying portion 140, and the RF applying unit 140 applies a high-frequency signal to the RF transmission coil portion 153 depending upon a control signal received from the pulse sequence controller 122 so as to transmit the RF pulse to the interior of the magnet assembly 150.

The RF applying portion 140 may include a modulation circuit to modulate a high-frequency signal into a pulse signal, and an RF power amplifier to amplify the pulse signal.

In addition, the RF reception coil 170 may receive RF signals (i.e., magnetic resonance signals) generated from the atomic nuclei. The RF reception coil 170 may transmit the magnetic resonance signal to the switching device 200, and the image processor 160 may form a magnetic resonance image by processing the magnetic resonance signal. In more detail, the image processor 160 may include a data collector 161 to collect magnetic resonance signals received from the RF reception coil and process the collected magnetic resonance signals; and a data processor to generate a magnetic resonance image using data received from the data collector 161.

The data collector 161 may include a preamplifier to amplify a magnetic resonance signal received by the RF reception coil 170; a phase detector to detect a phase upon receiving the magnetic resonance signal from the preamplifier; and an A/D converter to convert an analog signal acquired via phase detection into a digital signal. In addition, the data collector 161 transmits the digital magnetic resonance signal to the data storage 162.

In contrast, the RF reception coil 170 may include an amplifier to amplify the magnetic resonance signal received by the RF reception coil 170, and the data collector may not include the preamplifier.

The data storage 162 has a data space constituting a 2D Fourier space. When all scanned data is completely stored, the data processor 163 implements 2D inverse Fourier transformation of data in the 2D Fourier space to reconstruct an image of the object (ob). The reconstructed image may be displayed on the display 112.

A spin echo pulse sequence is mainly used to acquire a magnetic resonance signal from atomic nuclei. When a first RF pulse is applied to the RF transmission coil 153, an RF pulse is transmitted once more at an appropriate time interval Δt after the first RF pulse is applied. Thereby, a magnetic resonance signal may be acquired as atomic nuclei exhibit strong transversal magnetization when the time Δt has passed from application of the second RF pulse. This is referred to as a spin echo pulse sequence, and a time taken until the magnetic resonance signal is acquired after application of the first RF pulse is referred to as Time Echo (TE).

To what extent a proton has been flipped may be indicated by a movement angle from an axis at which the photon has been located prior to being flipped, and a 90° RF pulse or a 180° RF pulse appears based on a flip degree.

Meanwhile, the kind of the RF reception coil varies based on a region of the object (e.g., the human body) to be imaged. For example, the RF reception coil includes a head coil, a spine coil, a shoulder coil, a breast coil, a torso coil, a knee coil, a peripheral vascular (PV) coil, a foot-ankle coil, or the like.

The switching device 200 may receive magnetic resonance signals (i.e., RF signals) received by the RF reception coil through a plurality of input channels 310 capable of being connected to various kinds of RF reception coils. In more detail, the plurality of input channels 310 of the switching device 200 may be respectively allocated to the plurality of coils constructing various kinds of RF reception coils. As a result, the respective input channels 310 of the switching device 200 may receive RF signals received by the respective coils constructing various kinds of RF reception coils.

The switching device 200 may include a plurality of output channels 320 designed to output all or some of received RF signals, and the plurality of output channels 320 connected to the image processor 160 may output the RF signals, such that the RF signals can be transmitted to the image processor 160.

In this case, the switching device 200 may perform switching of the connection relationship between the plurality of input channels 310 and the plurality of output channels 320 so as to output only an RF signal received from the target object (ob) to be MR-imaged from among all RF signals applied to the respective input channels 310. Specifically, if the number of input channels 310 is different from the number of output channels 320, the switching device 200 may selectively transmit the received RF signal to the image processor 160 by switching the connection relationship between the input channels 310 and the output channels 320.

For this purpose, the general switching device 200 may include a plurality of switches designed to connect the respective input channels 320 to the respective output channels 320. In this case, the switching device 200 includes M input channels 310 and N output channels 320 needs to include (M×N) switches. The number of necessary switches geometrically increases in proportion to the increasing number of input channels 310 and output channels 320, such that the switching device 200 may encounter unexpected problems caused by a large-sized circuit, resulting in increased production costs. Since a large number of switches are controlled independently, there is a high level of difficulty in circuit configuration, resulting in occurrence of signal interference.

In addition, N output channels 320 of the switching device 200 may be connected to the image processor 160 having N input channels, or may be connected to the image processor 160 having N/2 input channels. In this case, it is necessary for the switching device 200 to have different numbers of output channels designed to output RF signals according to the number of input channels of the image processor 160 connected to the output channels 320.

Therefore, the switching device 200 is needed, which can simplify circuit configuration using a small number of switches and at the same time can output the same signal, and can change an output channel group designed to RF signals according to the selection result, and the magnetic resonance imaging (MRI) apparatus 100 including the switching device 200 is also needed.

The switching device 200 configured to address the above-mentioned issue will hereinafter be described.

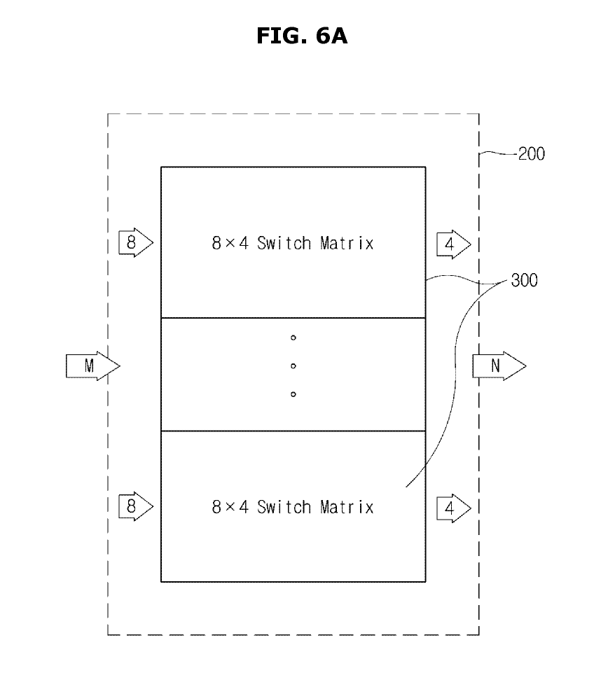

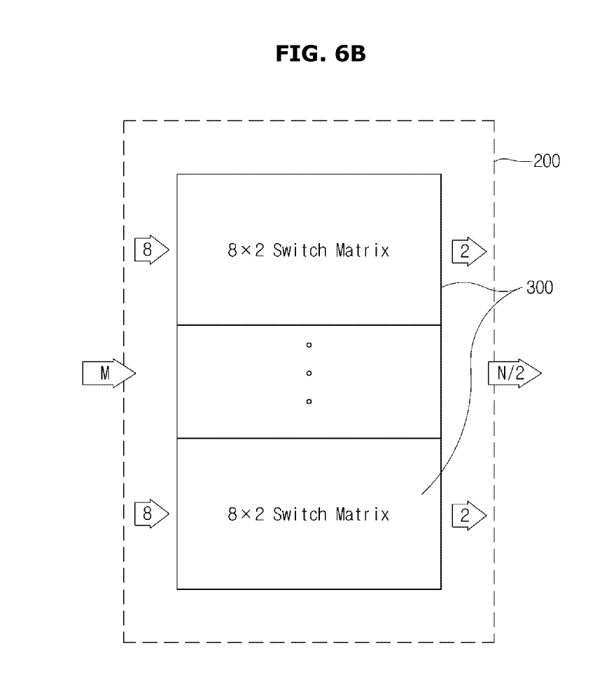

FIGS. 6A and 6B are conceptual diagrams illustrating various methods for allowing the switching apparatus to output signals according to an exemplary embodiment of the present disclosure. The switching device 200 of FIGS. 6A and 6B may exemplarily include M input channels 310 and N output channels 320. The M input channels 310 can be respectively connected to the plurality of coils constructing the RF reception coil 170, and the N output channels 320 may be connected to the image processor 160.

Referring to FIG. 6A, the (M×N) switching device 200 may be divided into switching cells 300. That is, the switching device 200 including M input channels 310 and N output channels 320 may include a plurality of switching cells 300 composed of 8 input channels 310 and 4 output channels 320. The plurality of switching cells 300 may be constructed separately from each other, such that the switching cells 300 can control not only 8 input channels 310 contained in one switching cell 300 but also 4 output channels 320.

If N input channels of the image processor 160 are connected to N output channels of the switching device 200, the switching device 200 may transmit N RF signals generated from N output channels to the image processor 160. For this purpose, 4 output channels of each switching cell 300 may output four RF signals.

In contrast, input channels of the image processor 160 may be connected only to some of N output channels. For example, N/2 input channels of the image processor 160 may be connected only to N/2 output channels from among N output channels of the switching device 200. In this case, the switching device 200 may perform switching of the connection relationship between the input channels and the output channels in a manner so that RF signals can be output through N/2 output channels connected to the input channels of the image processor 160.

In more detail, the switching device 200 may perform switching of the connection relationship between the input channels and the output channels in a manner so that only two output channels from among 4 output channels of each switching cell can output RF signals. As a result, the switching device 200 may operate in the same manner as in the case in which each switching cell 300 includes 8 input channels and 2 output channels as shown in FIG. 6B.

As described above, the switching device 200 according to the embodiment may variably control the output channels designed to output RF signals, without replacement or addition of hardware. Specifically, the above-mentioned operation is equally achieved at levels of respective switching cells 300 contained in the switching device 200, such that a single switching cell constructing the switching device 200 will hereinafter be described.

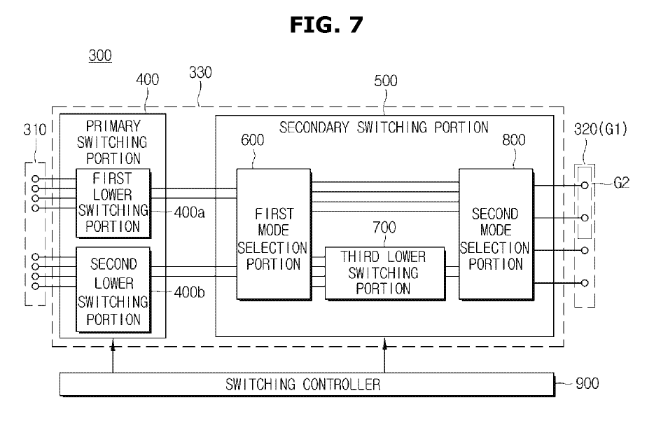

FIG. 7 is a control block diagram illustrating a switching cell according to an exemplary embodiment of the present disclosure.

Referring to FIG. 7, the switching cell 300 may include: 8 input channels 310 and 4 output channels 320; a switching portion 330 to switch the connection relationship among the 8 input channels and 4 output channels; and a switching controller 900 to control the switching portion 330.

The switching controller 900 may perform switching of the connection relationship between the input channels and the output channels by controlling a primary switching portion 400 and a secondary switching portion 500 contained in the switching portion 330. In more detail, the switching controller 900 may pre-select the mode of the switching portion 330 prior to operation of the switching device 200. A detailed description thereof will hereinafter be described with reference to the switching portion 330.

The switching controller 900 may be implemented as hardware such as a microprocessor. In contrast, the switching controller 900 may be implemented as software driven by hardware.

8 Input channels 310 may be connected to the RF reception coil 170. The 8 input channels 310 constructing the switching cell 300 may be respectively connected to the coils contained in the same RF reception coil 170, or may be connected to coils belonging to different kinds of RF reception coils 170.

4 output channels 320 may be connected to the image processor 160. RF signals generated from two output channels 320 may be converted into magnetic resonance images by the image processor 160.

In this case, 4 output channels 320 may change an output channel for outputting the RF signal according to a mode of the switching device 200. In more detail, all the four output channels 320 or two of the four output channels may output RF signals according to the mode of the switching device 200.

For this purpose, all the four output channels 320 may be determined to be a first output channel group, and two predetermined output channels from among the four output channels may be determined to be a second output channel group. In FIG. 7, the first output channel group may be denoted by G1, and the second output channel group may be denoted by G2.

The switching portion 330 may perform switching of the connection relationship between 8 input channels and 4 output channels (i.e., the first output channel group G1) or may perform switching of the connection relationship between some channels corresponding to the second output channel group G2.

For this purpose, the switching portion 330 may include a primary switching portion 400 for primarily switching a path of the RF signal received through the input channel; and a secondary switching portion 500 for switching an output channel through which the RF signal generated from the primary switching portion 400 is finally output.

The primary switching portion 400 may perform switching of the connection relationship between primary input channels (440a, 440b) connected to 8 input channels and primary output channels (450a, 450b). For this purpose, the primary switching portion 400 may include a first lower switching portion 400a and a second lower switching portion 400b. The first lower switching portion 400a may perform switching of the connection relationship between four input channels 440a from among 8 primary input channels (440a, 440b) and two output channels from among 4 primary output channels (450a, 450b). The second lower switching portion 400b may perform switching of the connection relationship between the remaining 4 input channels 440b from among 8 primary input channels (440a, 440b) and the remaining 2 output channels 450b from among the four primary output channels (450a, 450b).

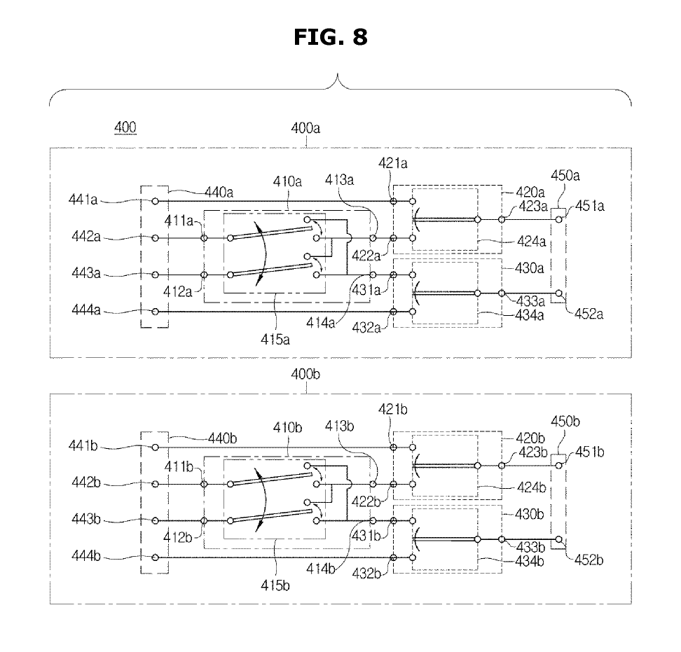

FIG. 8 is a circuit diagram illustrating a primary switching portion according to an exemplary embodiment of the present disclosure. The first lower switching portion 400a and the second lower switching portion 400b may have the same circuit structure, such that the same or similar structures as those described in the first lower switching portion 400a and the second lower switching portion 400b are denoted by the same reference numerals for convenience of description. However, in order to distinguish the circuit elements of the first lower switching portion 400a from the circuit elements of the second lower switching portion 400b, ‘a’ or ‘b’ may be added to the same reference numerals.

Although the circuit diagrams of the first lower switching portion 400a and the second lower switching portion 400b are shown in FIG. 8, the present disclosure will be described on the basis of the first lower switching portion 400a for convenience of description, and the second lower switching portion 400b may also operate in the same manner as in the first lower switching portion 400a.

As described above, the primary switching portion 400 according to one embodiment may include the first lower switching portion 400a and the second lower switching portion 400b.

The first lower switching portion 400a may perform switching of the connection relationship between four input channels 440a from among 8 primary input channels (440a, 440b) and two output channels 450a from among 4 primary output channels (450a, 450b). For this purpose, the first lower switching portion 400a may include a (1-1)-th lower switching portion 410a, a (1-2)-th lower switching portion 420a, and a (1-3)-th lower switching portion 430a.

The (1-1)-th lower switching portion 410a may perform switching of the path extending from two (442a, 443a) of four primary input channels 440a connected to the first lower switching portion 400a. For example, if the first lower switching portion 400a is connected to the second input channel 442a and the third input channel 443a from among the primary input channels, the (1-1)-th switching portion 410a may include the first lower input channel 411a connected to the second input channel 442a from among the primary input channels; the second lower input channel 412a connected to the third input channel 443a from among the primary input channels; the first lower output channel 413a and the second lower output channel 414a, and first switches 415a which connects the first lower input channel 411a to any one of the first lower output channel 413a and the second lower output channel 414a, and at the same time connects the second lower input channel 412a to the other one of the first lower output channel 413a and the second lower output channel 414a.

Referring to FIG. 8, the first switches 415a may connect the second lower input channel 412a to the second lower output channel 414a when the first lower input channel 411a is connected to the first lower output channel 413a. In contrast, the first switches 415a may connect the first lower input channel 411a to the second lower output channel 414a, and at the same time may connect the second lower input channel 412a to the first lower output channel 413a.

Consequently, if the first switches 415a forms a path from the first lower input channel 411a to the second lower output channel 413a and the other path from the second lower input channel 412a to the second lower output channel 414a, the RF signal received from the second input channel 442a from among the primary input channels may be output through the first lower output channel 413a, and the RF signal received from the third input channel 443a from among the primary input channels may be output through the second lower output channel 414a. In addition, if the first switch 415a forms a path from the first lower input channel 411a to the second lower output channel 414a and the other path from the second lower input channel 412a to the first lower output channel 413a, the RF signal received from the second input channel 442a from among the primary input channels may be output through the second lower output channel 414a, and the RF signal received from the third input channel 443a from among the primary input channels may be output through the first lower output channel 413a.

As described above, the (1-1)-th lower switching portion 410a controls the connection relationship among the first lower input channel 411a, the second lower input channel 412a, the first lower output channel 413a, and the second lower output channel 414a, such that the (1-1)-th lower switching portion 410a can switch a path extending from the second input channel 442a from among the primary input channels and the other path extending from the third input channel 443a from among the primary input channels.

Although the (1-1)-th lower switching portion 410a may be implemented as a Double Pole Double Throw (DPDT) format, the scope or spirit of the present disclosure is not limited thereto.

The (1-2)-th lower switching portion 420a may selectively connect either any one path formed by the (1-1)-th lower switching portion 410a or the first input channel 441a from among the primary input channels to the first output channel 451a. In addition, the (1-3)-th lower switching portion 430a may selectively either the other path formed by the (1-1)-th lower switching portion 410a or the fourth input channel 444a from among the primary input channels to the second output channel 452a from among the primary output channels.

For this purpose, the (1-2)-th lower switching portion 420a may selectively connect the first input channel 441a from among the primary input channels or the first lower output channel 413a of the (1-1)-th lower switching portion 410a to the first output channel 451a from among the primary output channels, and the (1-3)-th lower switching portion 430a may selectively connect the fourth input channel 444a from among the primary input channels or the second lower output channel 414a of the (1-1)-th lower switching portion 410a to the second output channel 452a from among the primary output channels.

Referring to FIG. 8, the (1-2)-th lower switching portion 420a may include a third lower input channel 421a connected to the first input channel 441a from among the primary input channels; a fourth lower input channel 422a connected to the first lower output channel 413a; a third lower output channel 423a connected to the first output channel 451a from among the primary output channels; and a second switch 424a for connecting any one of the third input channel 421a and the fourth lower input channel 422a to the third lower output channel 423a.

As a result, if the second switch 424a connects the third lower input channel 421a to the third lower output channel 423a, the RF signal received from the first input channel 441a from among the primary input channels may be output through the first output channel 451a from among the primary output channels. In contrast, if the second switch 424a connects the fourth lower input channel 422a to the third lower output channel 423a, the RF signal received from the second input channel 442a or the third input channel 443a may be output through the first output channel 451a from among the primary output channels.

As described above, since the (1-2)-th lower switching portion 420a selectively connects the third lower output channel 423a to the third lower input channel 421a or the fourth lower input channel 422a, the first output channel 451a from among the primary output channels may output the RF signal received through the first input channel 441a from among the primary input channels, the RF signal received through the second input channel 442a from among the primary input channels, or the RF signal received through the third input channel 443a from among the primary input channels.

Similar to the second (1-2)-th lower switching portion 420a, the (1-3)-th lower switching portion 430a may include a fifth lower input channel 431a connected to the second lower output channel 414a; a sixth lower input channel 432a connected to the fourth input channel 444a from among the primary input channels; a fourth lower output channel 433a connected to the second output channel 452a from among the primary output channels; and a third switch 434a for connecting any one of the fifth lower input channel 431a and the sixth lower input channel 432a to the fourth lower output channel 433a.

As a result, if the third switch 434a connects the fifth lower input channel 431a to the fourth lower output channel 433a, the RF signal received from the second input channel 442a or the third input channel 443a from among the primary input channels may be output through the second output channel 452a from among the primary output channels. In contrast, if the third switch 434a connects the sixth lower input channel 432a to the fourth lower output channel 433a, the RF signal received from the fourth input channel 444a from among the primary input channels may be output through the second output channel 452a from among the primary output channels.

As described above, since the (1-3)-th lower switching portion 430a selectively connects the fourth lower output channel 433a to the fifth lower input channel 431a or the sixth lower input channel 432a, the second output channel 452a from among the primary output channels may output the RF signal received through the second input channel 442a from among the primary input channels, the RF signal received through the third input channel 443a from among the primary input channels, or the RF signal received through the fourth input channel 444a from among the primary input channels.

Although each of the (1-2)-th lower switching portion 420a and the (1-3)-th lower switching portion 420a according to one embodiment can be implemented as a Single Pole Double Throw (SPDT) or Single Pole Two Throw (SP2T), the scope or spirit of the present disclosure is not limited thereto.

The switching cell 300 according to the above-mentioned embodiment may output all combinations, each of which is composed of two G2 signals from among 4 RF signals received through the input channel 310, as the output signal. This means that the switching cell according to one embodiment has the degree of freedom at which the switching cell can output a desired output signal in response to the input signal.

As can be seen from FIG. 8, each of the (1-2)-th lower switching portion 420a and the (1-3)-th lower switching portion 430a is implemented as SPDT or SP2T. However, each of the (1-2)-th lower switching portion 420a and the (1-3)-th lower switching portion 430a may also be implemented as DPDT.

Referring back to FIG. 7, the secondary switching portion 500 may switch the output channel 320 through which the RF signal generated from the primary switching portion 400 is finally output.

For this purpose, the secondary switching portion 500 may include a mode selection portion operated according to the selected mode; and a third lower switching portion 700 for switching the connection relationship between the second output channel group G2 and the secondary input channel 610 when a second mode is selected.

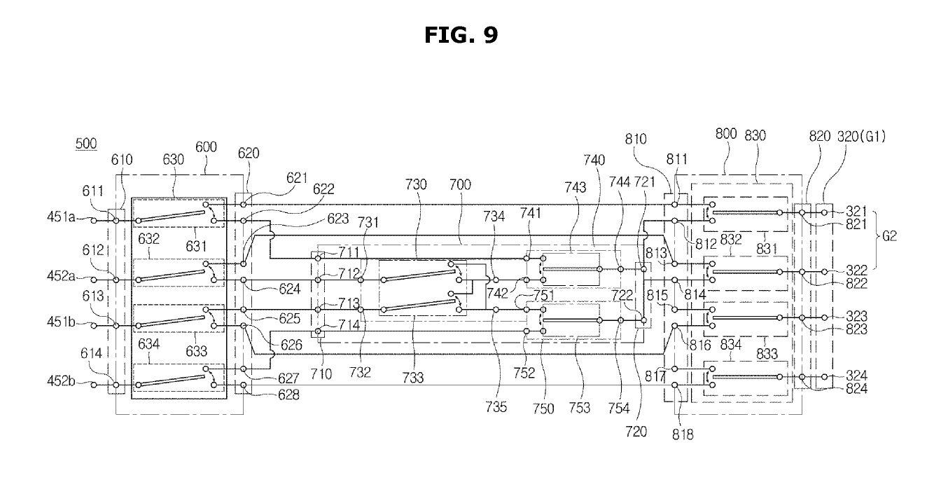

FIG. 9 is a circuit diagram illustrating a secondary switching portion according to an exemplary embodiment of the present disclosure.

Referring to FIG. 9, the mode selection portion may operate to connect the secondary input channel 610 to the secondary output channel 820 when a first mode is selected.

For this purpose, the mode selection portion may include a first mode selection portion 600 to form or block the path from the secondary input channel 610 of the secondary switching portion 500; and a second mode selection portion 800 to form or block the path to the secondary output channel 820 of the secondary switching portion 500.

The first mode selection portion 600 may include four secondary input channels 610, the 5^{th} to 12^{th} lower output channels, and a first mode selection switching portion 630 to connect any one of two lower output channels to one secondary input channel.

Referring to FIG. 9, the four secondary input channels may be respectively connected to four primary output channels (451a, 452a, 451b, 451b) of the primary switching portion 400. In addition, the respective secondary input channels 610 may be connected to the first mode selection switching portion 630.

The first mode selection switching portion 630 is connected to the secondary input channel 610, such that the first mode selection switching portion 630 can be connected to four lower output channels from among the 5^{th} to 12^{th} lower output channels 620. For this purpose, the first mode selection switching portion 630 may include a first mode selection switch 631 for connecting the first input channel 611 from among the secondary input channels 610 to either the 5^{th} lower output channel 621 or the 6^{th} lower output channel 622; a second mode selection switch 632 for connecting the second input channel 612 from among the secondary input channels 610 to either the 7^{th} lower output channel 623 or the 8^{th} lower output channel 624; a third mode selection switch 633 for connecting the third input channel 613 from among the secondary input channels 610 to either the 9^{th} lower output channel 625 or the 10^{th} lower output channel 626; and a fourth mode selection switch 634 for connecting the fourth input channel 614 from among the secondary input channels 610 to either the 11^{th} lower output channel 627 or the 12^{th} lower output channel 628.

Although each of the first to fourth mode selection switches 631-634 of the first mode selection switching portion 630 may be implemented as SPDT or SP2T, the scope or spirit of the present disclosure is not limited thereto.

The second mode selection portion 800 may include 8 lower input channels (i.e., 17^{th} to 24^{th} lower input channels; 810); secondary output channels 820; and a second mode selection switching portion 830 to connect any one of two lower input channels to one secondary output channel 820.

Referring to FIG. 9, the output channels 320 may be respectively connected to four secondary output channels 820 of the secondary switching portion 500. In addition, the secondary output channels 820 may be respectively connected to the second mode selection switching portion 830.

The second mode selection switching portion 830 is connected to the secondary output channel 820, such that the second mode selection switching portion 830 may operate to be connected to four lower input channels from among the 17^{th} to 24^{th} lower input channels. For this purpose, the second mode selection switching portion 830 may include a fifth mode selection switch 831 for connecting the first output channel 821 from among the secondary output channels 820 to either the 17^{th} lower input channel 811 or the 18^{th} lower input channel 812; a sixth mode selection switch 832 for connecting the second output channel 822 from among the secondary output channels 820 to either the 19^{th} lower input channel 813 or the 20^{th} lower input channel 814; a seventh mode selection switch 833 for connecting the third output channel 823 from among the secondary output channels 820 to either the 21^{st} lower input channel 815 or the 22^{nd} lower input channel 816; and an eighth mode selection switch 834 for connecting the fourth output channel 824 from among the secondary output channels 820 to either the 23^{rd} lower input channel 817 or the 24^{th} lower input channel 818.

Although each of the 5^{th} to 8^{th} mode selection switches 830 may be implemented as SPDT or SP2T, the scope or spirit of the present disclosure is not limited thereto.

If the second mode is selected, the third lower switching portion 700 may perform switching of the connection relationship between the second output channel group G2 and the secondary input channel 610. The third lower switching portion 700 is identical in structure and operation to the first lower switching portion 400a and the second lower switching portion 400b. For convenience of description and better understanding of the present disclosure, only the connection relationship by the third lower switching portion 700 in the secondary switching portion 500 will hereinafter be described in detail.

The third lower switching portion 700 may perform switching of the connection relationship between the 7^{th} to 10^{th} lower input channels and the 17^{th} to 18^{th} lower output channels.

The 7^{th} to 10^{th} lower input channels of the third lower switching portion 700 may be respectively connected to the 6^{th} lower output channel 622, the 8^{th} lower output channel 624, the 10^{th} lower output channel 626, and the 12^{th} lower output channel 628 of the first mode selection portion 600.

In addition, the 8^{th} lower input channel 712 and the 9^{th} lower input channel 713 may be respectively connected to the 11^{th} lower input channel 731 and the 12^{th} lower input channel 732 of the (3-1)-th lower switching portion 730. When the 11^{th} lower input channel 731 is connected to the 13^{th} lower output channel 734, the lower switching portion 330 may connect the 12^{th} lower input channel 732 to the 14^{th} lower output channel 735. In contrast, when the 11^{th} lower input channel 731 is connected to the 14^{th} lower output channel 735m the lower switching portion 330 may connect the 12^{th} lower input channel 732 to the 13^{th} lower output channel 734. For this purpose, the lower switching portion 330 may include the fourth switch 733 in the same manner as in the first switches 415a of FIG. 8.

In addition, the 7^{th} lower input channel 711 and the 13^{th} lower output channel may be respectively connected to the 13^{th} lower input channel 741 and the 14^{th} lower input channel 742 of the (3-2)-th lower switching portion 740, and the 14^{th} lower output channel 735 and the 10^{th} lower input channel 714 may be respectively connected to the 15^{th} lower input channel 751 and the 16^{th} lower input channel 752 of the (3-3)-th lower switching portion 750.

The (3-2)-th lower switching portion 740 may include a fifth switch 743 for connecting the 15^{th} lower output channel 744 connected to the 17^{th} lower output channel 721 to the 13^{th} lower input channel 741 or the 14^{th} lower input channel 742, and the fifth switch 743 may be identical to the second switch 424a of FIG. 8.

The (3-3)-th lower switching portion 750 may include a sixth switch 753 for connecting the 16^{th} lower output channel 754 connected to the 18^{th} lower output channel 722 to the 15^{th} lower input channel 751 or the 16^{th} input channel 752, and the sixth switch 753 may be identical to the third switch 434a of FIG. 8.

The secondary switching portion 500 has been disclosed as described above.

As described above, the switching controller 900 may pre-select the mode of the switching portion 330 prior to operation of the switching device 200. In this case, the mode of the switching portion 330 may be pre-selected by inner operation of the switching controller 900 or by a user input signal.

The mode of the switching portion 330 may be classified into a first mode and a second mode. The first mode is a mode for outputting the RF signal through the first output channel group G1 corresponding to four output channels of the switching cell 300. In addition, the second mode is a mode for outputting the RF signal through only the second output channel group G2 corresponding to two of the four output channels of the switching cell 300.

If the mode is selected, the switching controller 900 may control the secondary switching portion 500 in response to the selected mode.

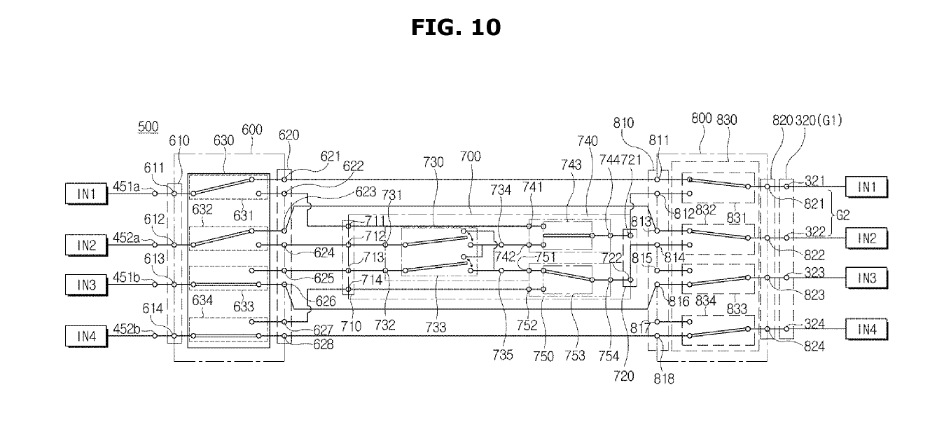

FIG. 10 is a circuit diagram illustrating the operations generated when a first mode of the secondary switching portion is selected.

Referring to FIG. 10, if the first mode is selected, the mode selection portion may form the path through which the respective secondary input channels 610 can be sequentially connected to the respective secondary output channels 820. That is, the mode selection portion may connect the first input channel 611 from among the secondary input channels 610 to the first output channel 821 from among the secondary output channels 820, may connect the second input channel 612 from among the secondary input channels 610 to the second output channel 822 from among the secondary output channels 820, may connect the third input channel 613 from among the secondary input channels 610 to the third output channel 823 from among the secondary output channels 820, and may connect the path through which the fourth input channel 614 from among the secondary input channels 610 is connected to the fourth output channel 824 from among the secondary output channels 820.

For this purpose, the first mode selection switch 631 may connect the first input channel 611 from among the secondary input channels 610 to the fifth lower output channel 621, and the fifth mode selection switch 831 may connect the first output channel 821 from among the secondary output channels 820 to the 17^{th} lower output channel 721. As a result, the signal IN1 applied to the first input channel 611 from among the secondary input channels 610 may be output to the first output channel 821 from among the secondary output channels 820.

In addition, the second mode selection switch 632 may connect the second input channel 612 from among the secondary input channels 610 to the seventh lower output channel 623, and the sixth mode selection switch 832 may connect the second output channel 822 from among the secondary output channels 820 to the 19^{th} lower output channel. As a result, signal IN2 applied to the second input channel 612 from among the secondary input channels 610 may be output to the second output channel 822 from among the secondary output channels 820.

In addition, the third mode selection switch 633 may connect the third input channel 613 from among the secondary input channels 610 to the 10^{th} lower output channel 626, and the seventh mode selection switch 833 may connect the third output channel 832 from among the secondary output channels 820 to the 22^{nd} lower output channel. As a result, the signal IN3 applied to the third input channel 613 from among the secondary input channels 610 may be output to the third output channel 823 from among the secondary output channels 820.

In addition, the fourth mode selection switch 634 may connect the fourth input channel 614 from among the secondary input channels 610 to the 12^{th} lower output channel 628. The 8^{th} selection switch 834 may connect the fourth output channel 824 from among the secondary output channels 820 to the 24^{th} lower output channel. As a result, signal IN4 applied to the fourth input channel 614 from among the secondary input channels 610 may be output to the fourth output channel 824 from among the secondary output channels 820.

As described above, if the first mode is selected, the mode selection portion may form the path through which signals IN1 to IN4 do not pass through the third lower switching portion 700. As a result, input signals IN1 to IN4 may be output through the first output channel group G1 corresponding to four output channels.

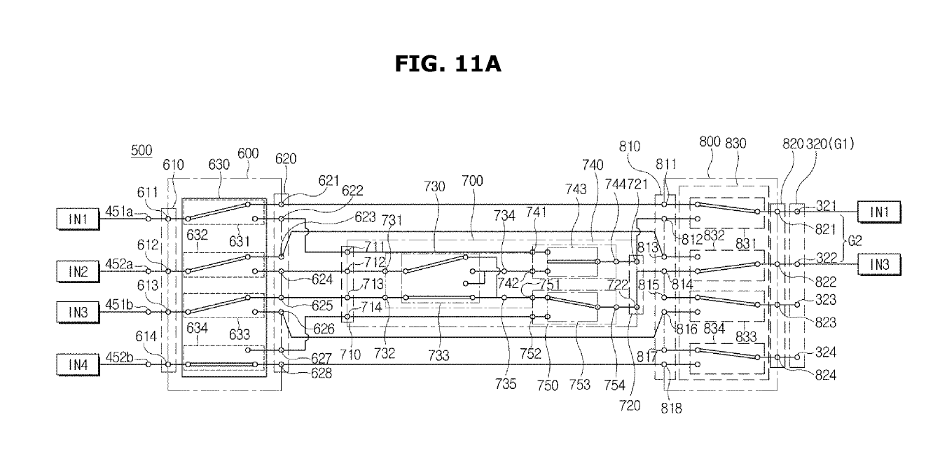

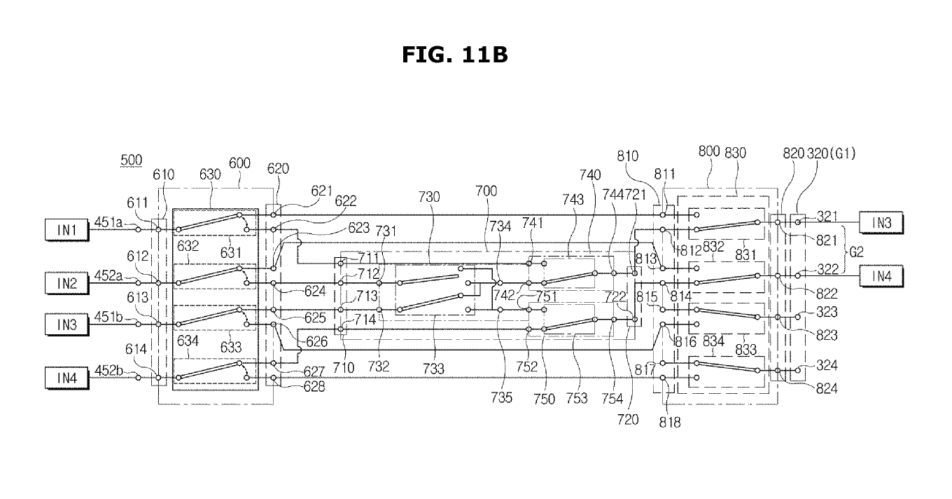

FIGS. 11A and 11B are circuit diagrams illustrating the operations generated when a second mode of the secondary switching portion is selected.

As described above, if the second mode is selected, only two output channels from among four output channels need to output RF signals. Therefore, if the second mode is selected, it may be possible to output RF signals received through the path formed by the third lower switching portion 700.

FIG. 11A exemplarily illustrates that signal IN1 applied to the first input channel 611 from among the secondary input channels 610 and signal IN3 applied to the third input channel 613 from among the secondary input channels 610 are output through the second output channel group G2.

For this purpose, the first mode selection switch 631 may connect the first input channel 611 from among the secondary input channels 610 to the fifth lower output channel 621, and the fifth mode selection switch 831 may connect the first output channel 821 from among the secondary output channels 820 to the 17^{th} lower output channel 811. As a result, the signal IN1 applied to the first input channel 611 from among the secondary input channels 610 may be output to the first output channel 821 from among the secondary output channels 820.

In addition, the third mode selection switch 633 may connect the third input channel 613 from among the secondary input channels 610 to the ninth lower output channels 625, such that the third mode selection switch 633 can form the path through which the signal IN3 goes to the ninth lower input channel 713 of the third lower switching portion 700. Thereafter, the fourth switch 733 of the third lower switching portion 700 may connect the ninth lower input channel 713 to the 14^{th} lower output channel 735, and the sixth switch 753 may connect the 15^{th} input channel 751 connected to the 14^{th} lower output channel 735 to the 16^{th} lower output channel 754 connected to the 18^{th} lower output channel 722. Finally, the sixth mode selection switch 832 may connect the second output channel 822 from among the secondary output channels 820 to the 20^{th} lower input channel 814 connected to the 18^{th} lower output channel 722. As a result, it may be possible to form the path for connecting the third input channel 613 from among the secondary input channels 610 to the second output channel 822 from among the secondary output channels 820.

FIG. 11B illustrates another exemplary case in which the signal IN3 applied to the third input channel 613 from among the secondary input channels 610 and the signal IN4 applied to the fourth input channel 614 from among the secondary input channels 610 are output through the second output channel group G2.

For this purpose, the third mode selection switch 633 may connect the third input channel 613 from among the secondary input channels 610 to the ninth lower output channel 625, and it may be possible to form the path through which signal IN3 goes to the ninth lower input channel 713 of the third lower switching portion 700. Thereafter, the fourth switch 733 of the third lower switching portion 700 may connect the ninth lower input channel 713 to the 13^{th} lower output channel 734, and the fifth switch 743 may connect the 14^{th} input channel 742 connected to the 13^{th} lower output channel 734 to the 15^{th} lower output channel 744 connected to the 17^{th} lower output channel 721. Finally, the fifth mode selection switch 831 may connect the first output channel 821 from among the secondary output channels 820 to the 18^{th} lower input channel 812 connected to the 17^{th} lower output channel 721. As a result, it may be possible to form the path for connecting the third input channel 613 from among the secondary input channels 610 to the first output channel 821 from among the secondary output channels 820.

In addition, the fourth mode selection switch 634 may connect the fourth input channel 614 from among the secondary input channels 610 to the 11^{th} lower output channels 627, such that the fourth mode selection switch 634 can form the path through which the signal IN4 goes to the 10^{th} lower input channel 714 of the third lower switching portion 700. Thereafter, the sixth switch 753 may connect the 16^{th} lower input channel 752 connected to the 10^{th} lower input channel 714 to the 16^{th} lower output channel 754. Finally, the sixth mode selection switch 832 may connect the second output channel 822 from among the secondary output channels 822 to the 20^{th} lower input channel 814 connected to the 18^{th} lower output channel 722. As a result, it may be possible to form the path for connecting the third input channel 613 from among the secondary input channels 610 to the second output channel 822 from among the secondary output channels 820.

As described above, the switching device 200 according to one embodiment may variably control the number of output channels configured to output RF signals in a different way from the number of actually implemented output channels. As a result, it may be possible to provide a universal switching device 200 capable of being flexibly operated in response to the number of input channels.

In addition, each of the switching device 200 and the image processor 160 connected thereto may be implemented as a single board. If the image processor 160 includes a smaller number of input channels than the number of output channels provided in the switching device 200, RF signals desired to be output are transmitted to the output channels connected to the input channels of the image processor 160, resulting in reduction of the number of boards used in the MRI apparatus 100.

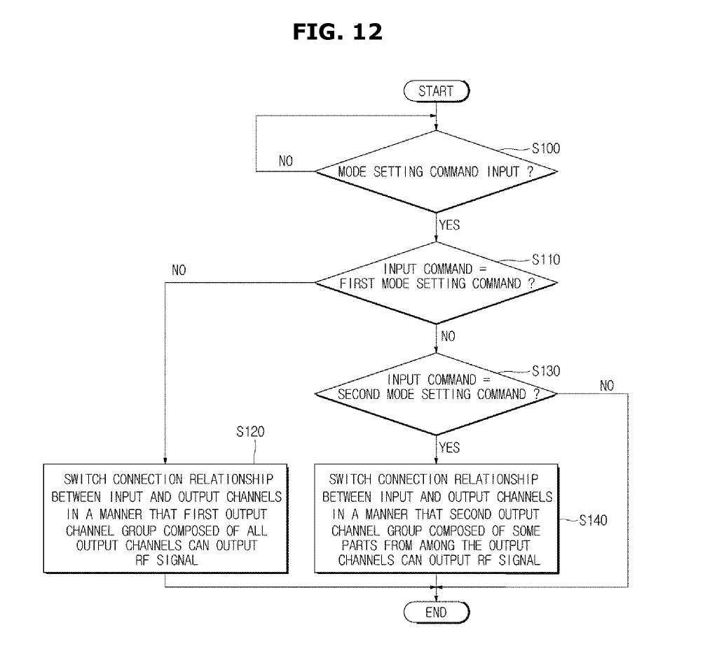

FIG. 12 is a flowchart illustrating a method for controlling the switching apparatus according to an exemplary embodiment of the present disclosure.

Referring to FIG. 12, the switching device 200 may determine whether a mode setting command is input (S100). The mode setting command may be directly entered by the user, and may be generated by inner calculation of the switching device 200. If the mode setting command is not yet input, the switching device 200 may repeatedly confirm whether or not the mode setting command is not yet input.

If the mode setting command is input, the switching device 200 may determine whether the input command is a first mode setting command (S110). In this case, the first mode may indicate a mode of the switching device 200 capable of outputting RF signals through all the output channels.

If the first mode setting command is input, the switching device 200 may perform switching of the connection relationship between the input channel and the output channel in a manner so that the first output channel group G1 comprised of all the output channels can output RF signals (S120).

If the input command is not identical to the first mode setting command, the switching device 200 may determine whether the input command is the second mode setting command (S130).

If the second mode setting command is input, the switching device 200 can perform switching of the connection relationship between the input and output channels in a manner so that the second output channel group G2 comprised of some predetermined parts from among the output channels can output RF signals (S140).

If such switching is completed, or if the input of the second mode setting command is not confirmed, all the procedures are terminated.

As is apparent from the above description, the switching apparatus, the magnetic resonance imaging (MRI) apparatus, and the method for controlling the MRI apparatus according to exemplary embodiments of the present disclosure can variably change an output channel group configured to variably output RF signals according to a selection mode.

As a result, the exemplary embodiments can transmit input RF signals to an image processor without replacing or adding the switching apparatus even when the number of input channels of the image processor connected to the output channel is changed, resulting in reduction of production costs of the MRI apparatus including the switching apparatus.

Although a few exemplary embodiments of the present disclosure have been shown and described, it would be appreciated by those skilled in the art that changes may be made in these exemplary embodiments without departing from the principles and spirit of the invention, the scope of which is defined in the claims and their equivalents.

What is claimed is:

1. A switching device comprising:
a plurality of input channels configured to be respectively connected to a plurality of coils, the plurality of input channels receiving a plurality of radio frequency (RF) signals from a target object to which a magnetic field is applied;
a plurality of output channels configured to be connected to an image processor, the image processor being configured to generate a magnetic resonance image based on the received plurality of RF signals; and
a switching portion configured to switch a connection relationship between the plurality of input channels and the plurality of output channels,
wherein,
if a first mode is selected, the switching portion is further configured to switch the connection relationship in a manner so that a first output channel group including the plurality of output channels outputs the plurality of RF signals, and
if a second mode is selected, the switching portion is further configured to switch the connection relationship in a manner so that a second output channel group including predetermined parts from among the plurality of output channels, outputs the plurality of RF signals.

2. The switching device according to claim 1, wherein:
a number of output channels in the first output channel group is twice a number of output channels in the second output channel group; and
a number of input channels is twice a number of output channels in the first output channel group.

3. The switching device according to claim 1, wherein the switching portion comprises:
a plurality of switching cells, each of which is configured to perform switching of a connection relationship between eight input channels and four output channels.

4. The switching device according to claim 3, wherein:
if the first mode is selected, one of the plurality of the switching cells is further configured to switch the connection relationship in a manner so that the first output channel group including all the four output channels, outputs the plurality of RF signals; and
if the second mode is selected, the one of the plurality of switching cells is further configured to switch the connection relationship in a manner so that the second output channel group including two output channels from among the four output channels, outputs the plurality of RF signals.

5. The switching device according to claim 4, wherein the switching cell comprises:
a primary switching portion configured to perform switching of a connection relationship between primary input channels connected to the eight input channels and the four primary output channels; and
a secondary switching portion configured to perform switching of a connection relationship between the four primary output channels and the first output channel group when the first mode is selected, and configured to perform switching of a connection relationship between the four primary output channels and the second output channel group when the second mode is selected.

6. The switching device according to claim 5, wherein the primary switching portion comprises:
a first lower switching portion configured to perform switching of a connection relationship between four of the primary input channels and two of the primary output channels; and
a second lower switching portion configured to perform switching of a connection relationship between the remaining four of the primary input channels and the remaining two of the primary output channels.

7. The switching device according to claim 5, wherein the secondary switching portion comprises:
a third lower switching portion configured to perform switching of a connection relationship between secondary input channels connected to the four primary output channels and two secondary output channels connected to the second output channel group when the second mode is selected,
wherein the secondary switching portion further comprises:
a mode selection portion configured to connect the four primary output channels to the first output channel group when the first mode is selected.

8. A magnetic resonance imaging apparatus comprising:
a radio frequency (RF) coil in which a plurality of coils receives a plurality of RF signals from a target object to which a magnetic field is applied, is arranged;
an image processor configured to generate a magnetic resonance image based on the received plurality of RF signals; and
a switching device configured to perform switching of a connection relationship between a plurality of input channels operable to be connected to the plurality of coils and a plurality of output channels operable to be connected to the image processor,
wherein,
if a first mode is selected, the switching device performs switching of the connection relationship in a manner so that a first output channel group including the plurality of output channels outputs the plurality of RF signals, and
if a second mode is selected, the switching device performs switching of the connection relationship in a manner so that a second output channel group including predetermined parts from among the plurality of output channels outputs the plurality of RF signals.

9. The magnetic resonance imaging apparatus according to claim 8, wherein:
a number of output channels in the first output channel group is twice a number of output channels in the second output channel group; and
a number of input channels is twice a number of output channels in the first output channel group.

10. The magnetic resonance imaging apparatus according to claim 8, wherein the switching device comprises:
a plurality of switching cells, each of which is configured to perform switching of a connection relationship between eight input channels and four output channels.

11. The magnetic resonance imaging apparatus according to claim 10, wherein:
if the first mode is selected, one of the plurality of the switching cells is further configured to switch the connection relationship in a manner so that the first output channel group including all the four output channels, outputs the plurality of RF signals; and
if the second mode is selected, the one of the plurality of switching cells is further configured to switch the connection relationship in a manner so that the second output channel group including two output channels from among the four output channels, outputs the plurality of RF signals.

12. The magnetic resonance imaging apparatus according to claim 11, wherein the switching cell comprises:
a primary switching portion configured to perform switching of a connection relationship between primary input channels connected to the eight input channels and four primary output channels; and
a secondary switching portion configured to perform switching of a connection relationship between the four primary output channels and the first output channel group when the first mode is selected, and configured to perform switching of a connection relationship between the four primary output channels and the second output channel group when the second mode is selected.

13. The magnetic resonance imaging apparatus according to claim 12, wherein the primary switching portion comprises:
a first lower switching portion configured to perform switching of a connection relationship between four of the primary input channels and two of the primary output channels; and
a second lower switching portion configured to perform switching of a connection relationship between the remaining four of the primary input channels and the remaining two of the primary output channels.

14. The magnetic resonance imaging apparatus according to claim 12, wherein the secondary switching portion comprises:
a third lower switching portion configured to perform switching of a connection relationship between secondary input channels connected to the four primary output channels and two secondary output channels connected to the second output channel group when the second mode is selected,
wherein the secondary switching portion further comprises:
a mode selection portion configured to connect the four primary output channels to the first output channel group when the first mode is selected.

15. A method for controlling a magnetic resonance imaging apparatus which includes a switching device configured to perform switching of a connection relationship between a plurality of input channels operable to be connected to a plurality of coils receiving a plurality of radio frequency (RF) signals from a target object and a plurality of output channels operable to be connected to an image processor, the method comprising:
confirming a selected mode of the switching device; and
switching the connection relationship according to the selected mode,
wherein the switching the connection relationship comprises:
if a first mode is selected by the switching device, switching the connection relationship in a manner so that a first output channel group including the plurality of output channels outputs the plurality of RF signals, and
if a second mode is selected by the switching device, switching the connection relationship in a manner so that a second output channel group including predetermined parts from among the plurality of output channels outputs the plurality of RF signals.

16. The method according to claim 15, wherein:
a number of output channels in the first output channel group is twice a number of output channels in the second output channel group; and
a number of input channels is twice a number of output channels in the first output channel group.

17. The method according to claim 15, wherein the switching device includes:
a plurality of switching cells, each of which is configured to perform switching of a connection relationship between eight input channels and four output channels,
wherein the switching the connection relationship according to the selected mode includes switching a connection relationship between the respective switching cells according to the selected mode.

18. The method according to claim 17, wherein:
the switching the connection relationship when a first mode is selected by the switching device comprises switching the connection relationship in a manner so that the first output channel group including all the four output channels of the switching cell outputs the plurality of RF signals; and
the switching the connection relationship when a second node is selected by the switching device comprises switching the connection relationship in a manner so that the second output channel group including two output channels from among the four output channels of the switching cell outputs the plurality of RF signals.

19. The method according to claim 18, wherein:
the switching the connection relationship according to the selected mode further comprises:
switching a connection relationship between primary input channels of a primary switching portion of the switching cell connected to the eight input channels and four primary output channels of the primary switching portion of the switching cell,
the switching the connection relationship when the first mode is selected by the switching device comprises:
switching a connection relationship between the four primary output channels and the first output channel group; and
the switching the connection relationship when the second mode is selected by the switching device comprises:
switching a connection relationship between the four primary output channels and the second output channel group.

20. The method according to claim 19, wherein:
the switching the connection relationship when the second mode is selected by the switching device comprises:
switching a connection relationship between a secondary input channel of a secondary switching portion of the switching cell connected to the four primary output channels and two secondary output channels of the secondary switching portion of the switching cell connected to the second output channel group; and
the switching the connection relationship when the first mode is selected by the switching device comprises:
connecting the four primary output channels to the first output channel group.
